(19) United States
(12) Patent Application Publication
(10) Pub. No.: US 2026/0128264 A1
(43) Pub. Date: May 7, 2026

(54) PARTICLE CONTAMINATION CONTROL IN A PLASMA AFTERGLOW

(71) Applicant: UNIVERSITY OF IOWA RESEARCH FOUNDATION, Iowa City, IA (US)

(72) Inventors: John GOREE, Iowa City, IA (US); Neeraj CHAUBEY, Iowa City, IA (US)

(73) Assignee: UNIVERSITY OF IOWA RESEARCH FOUNDATION, Iowa City, IA (US)

(21) Appl. No.: 19/114,336

(22) PCT Filed: Sep. 21, 2023
(86) PCT No.: PCT/US2023/033392

§ 371 Date: Mar. 21, 2025

Related U.S. Application Data
(60) Provisional application No. 63/408,717, filed on Sep. 21, 2022.
(60) Provisional application No. 63/378,662, filed on Oct. 6, 2022.

(51) Int. Cl. H01J 37/32

(52) U.S. Cl. CPC H01J 37/32871; H01J 37/32146; H01J 37/32174; H01J 2237/334

(57) ABSTRACT

Apparatus, methods, and systems are disclosed for controlling a charge on a particle in a plasma chamber and for controlling a lifting force on a particle in a plasma chamber. Controlling the lifting force, F˜QE, in a plasma afterglow, is achieved using a combination of two separate potentials during the afterglow. These potentials, one for controlling the charge on the panicle and one for controlling the lifting force, are applied to one or more electrodes of the plasma chamber at different times.

### CROSS-REFERENCE TO RELATED APPLICATIONS

This application claims priority to U.S. Provisional Patent Application No. 63/408,717, filed 21 Sep. 2022, and to U.S. Provisional Patent Application No. 63/378,662, filed 6 Oct. 2022. The entire content of U.S. Provisional Patent Application No. 63/408,717 and U.S. Provisional Patent Application No. 63/378,662 is hereby incorporated herein by reference.

### STATEMENT REGARDING FEDERALLY SPONSORED RESEARCH

This invention was made with government support under MURI Grant No. W91INF-18-1-0240, awarded by the Army Research Office, Grant No. DE-SC0014566, awarded by the United States Department of Energy, RSA 1663801, 1672641, and 1689926, subcontracts awarded by NASA/JPL, PHY-1740379, awarded by the National Science Foundation. The government bas certain rights in the invention.

### FIELD

The present invention relates to semiconductor manufacturing. More particularly, but not exclusively, the present invention relates to methods and systems for applying and controlling the lifting force of particles in a plasma afterglow.

### BACKGROUND

During semiconductor manufacturing, plasmas are used for processing substrates such as semiconductor wafers. The processing has purposes such as deposition of layers on a substrate using plasma enhanced chemical vapor deposition (PECVD), atomic layer deposition (ALD), etching of layers on a substrate, production of an ion beam for implantation on a substrate, or lithography using a plasma-generated light source.

Generally, gases are introduced into a plasma chamber or plasma chamber and then the plasmas may be initiated by applying a direct current, a radio-frequency (RF) signal, or microwave signals to the gases. Once the power signal that sustains a plasma glow discharge is switched off there is a temporal plasma afterglow. During these plasma processing steps, an unwanted contamination often occurs, by small solid particles, sometimes referred to as dust particles, typically less than one micron in size, falling onto the substrate. The source of these particles can include a release from surfaces or growth in the gas phase by nucleation and coagulation. This substrate is typically positioned at the bottom of a plasma chamber, facing upward. The time that this particulate contamination occurs is in many cases when the plasma is extinguished. Small particles that previously were electrically suspended in the plasma, or in the plasma-boundary region called a sheath, fall down to the substrate, causing defects which result in “yield loss” in the manufacturing process.

What is needed are new and improved methods, apparatus, and systems for reducing particulate contamination and therefore yield loss in semiconductor manufacturing processes.

### SUMMARY

Therefore, it is a primary object, feature, or advantage to improve over the state of the art.

It is a further object, feature, or advantage to improve semiconductor manufacturing by reducing particulate contamination and yield loss.

It is a still further object, feature, or advantage to control lifting force on particles in plasma afterglow.

One or more of these and/or other objects, features, or advantages will be apparent from the specification and claims that follow. No single embodiment need exhibit each and every object, feature, or advantage as different embodiments may have different objects, features, and advantages.

According to one aspect, a method for controlling the lifting force of particles in plasma afterglow in semiconductor manufacturing is provided. The method includes potentials on at least one electrode, that do not always remain unchanged. In the first step, the potential helps to control a residual charge, Q, that will remain on the particle at later times. The potential in this first step may be a spontaneously generated, e.g., a self-bias potential that was established while the RF plasma was powered, or the potential in the first step may be applied by an external DC power supply. After the first step, there can be one or more potentials applied to further control the residual charge, Q. The final step, will have a potential applied that helps control the lifting force acting on the particle due to its residual charge, by controlling the electric field E that acts on the residual charge Q, to lift the particle in opposition to gravity. The lifting force is a product of a residual charge, Q, and the electric field, E. This final step for controlling the electric field and lifting force may have sub-steps with different potentials applied and/or different electrodes used. Overall, the minimum number of steps is two, with the first step controlling the residual charge and the final step controlling the lifting force. Any additional steps between the first and last step can serve either for controlling the charge, or controlling the lifting force, or a combination of both. In each step, the potential will be applied for a period of time to a particular electrode or electrodes, or other conducting surface. The potential in the second step, and in each step after that, may be applied with an external direct current (DC) power supply. The potential in the first step may have a different magnitude than the potential applied in the second step and any steps thereafter. The method may further include removing the particles from the plasma chamber. The method may further include observing the particles in the plasma chamber during the plasma afterglow. The observing may be performed using at least one camera such as a top-view camera and/or a side-view camera.

According to another aspect, a system for semiconductor manufacturing includes a plasma chamber, a platform disposed within the chamber for supporting a substrate, a gas supply and pumping system to supply a gas to the plasma chamber and evacuate gas, at least one signal generator for introducing power into the plasma chamber to sustain the ionization of the plasma for a period of time, at least one DC voltage source, and a control system operatively connected to the at least one DC voltage source wherein the control system is configured to apply a first potential at a first time and a second potential at a second time in order to control a lifting force of particles within the plasma chamber during plasma afterglow. The system may further include at least one sensor configured to observe particles within the chamber such as a top-view camera, a side-view camera, and/or a laser beam instrument. The signal generator may be an RF signal generator. The system may further include at least one sensor to monitor the temporal decay of plasma in the afterglow.

According to another aspect, a method for controlling lifting force of particles in plasma afterglow in semiconductor manufacturing is provided. The method includes controlling a residual charge, Q, which remains after extinguishing power to one or more electrodes of a plasma chamber. The method further includes separately controlling the lifting force, F, for the particles in the plasma afterglow by controlling the electric field, E, such that F=QE, the lifting force in opposition to gravity. The controlling the residual charge may be at least partially performed by changing radio frequency (RF) amplitude prior to the extinguishing power to adjust self-bias. The controlling the residual charge may include applying at least one direct current (DC) potential to the one or more electrodes of the plasma chamber. The step of applying the at least one DC potential to the one or more electrodes of the plasma chamber may be performed when the power to the one or more electrodes of the plasma chamber is extinguished. The method may further include applying at least one DC potential to the one or more electrodes of the plasma chamber to both finish the controlling of the residual charge and start the controlling the electric field. The step of controlling the electric field may be performed by applying DC potential to the one or more electrodes. The step of applying the DC potential may be performed during a period when non-downward forces are applied to move particles away from a substrate. The method may further include observing the particles in the plasma chamber during the plasma afterglow. The observing may be performed using at least one camera such as a top-view camera and/or a side-view camera.

According to another aspect, a system for semiconductor manufacturing includes a plasma chamber, a platform disposed within the chamber for supporting a substrate, a gas supply to supply a gas to the plasma chamber, a signal generator for periodically introducing power into the plasma chamber at one or more electrodes to partially ionize the gas into plasma, and a control system operatively connected to the signal generator and configured to control lifting force for particles in the plasma chamber during plasma afterglow by controlling the electric field, E, the lifting force determined from F=QE where a residual charge, Q, remains after extinguishing power to the one or more electrodes of the plasma chamber, wherein the lifting force is in opposition to gravity. The system may further include at least one DC voltage source operatively connected to the control system and wherein the control system is configured to apply one or more DC potentials to the one or more electrodes to control at least one of the residual charge, Q, and the electric field, E. The control system may be configured to adjust amplitude of a signal from the signal generator to adjust self-bias before extinguishing the power into the plasma chamber. The system may further include at least one sensor configured to observe particles within the chamber which may include a top-view camera, a side-view camera, and/or a laser beam instrument. The signal generator may be an RF signal generator. The system may further include at least one DC voltage source operatively connected to the control system and wherein the control system is configured to apply in sequence a first direct current (DC) potential to the one or more electrodes of the plasma chamber to control the residual charge and a second direct current (DC) potential to the one or more electrodes of the plasma chamber to control the electric field.

Consistent with disclosed embodiments, a method for controlling a charge on a dust particle during a plasma afterglow is disclosed. The method comprises controlling a voltage signal between at least two of a plurality of electrodes included in a plasma chamber after a delay time after a power signal at the at least two of the plurality of electrodes is turned off, to control the charge. In some embodiments, controlling the voltage signal comprises for the voltage signal having a polarity and magnitude, controlling the polarity of the voltage signal and controlling the magnitude of the voltage signal. In some embodiments, the power signal is a radio frequency power signal.

In some embodiments, the delay time is less than about one hundred milliseconds. In some embodiments, the charge is between about ˜10e and about +10e per nanometer of diameter or length of the dust particle. In some embodiments, the plasma chamber is included in an extreme ultraviolet lithography system.

Consistent with disclosed embodiments, a method for controlling a charge on a dust particle is disclosed. The method comprises delivering a radio frequency power signal to at least two of a plurality of electrodes included in a plasma chamber, and turning the radio frequency power signal on and off, to control the charge. In some embodiments, the method further comprises varying the rate at which the radio frequency power signal is turned on and off. In some embodiments, turning the radio frequency power signal on and off, to control the charge comprises turning the radio frequency power on and off to cause the charge to have a negative value.

Consistent with disclosed embodiments, a method for controlling a charge on a dust particle during a plasma afterglow is disclosed. The method comprises turning a power signal at two of the plurality of electrodes on and off to control the charge. In some embodiments, turning the power signal at two of the plurality of electrodes on and off to control the charge comprises turning a radio frequency signal at two of the plurality of electrodes on and off to control the charge.

Consistent with disclosed embodiments, a method for controlling lifting of a dust particle in a plasma in a plasma chamber including a plurality of electrodes, the dust particle having a charge, is disclosed. The method comprises removing a power signal at one of a plurality of electrodes between two of the plurality of electrodes at a power signal turn-off time; and applying a voltage signal between the two of the plurality of electrodes after a delay time starting at the power signal turn-off time to generate an electric field to control the lifting of the dust particle and thereby substantially prevent the dust particle from falling. In some embodiments, applying the voltage signal between the two of the plurality of electrodes after the delay time starting at the power signal turn-off time to generate the electric field to substantially prevent the dust particle from falling comprises applying a positive voltage or a negative voltage between the two of the plurality of electrodes after the delay time sufficient to substantially freeze the charge. In some embodiments, applying the voltage signal between the two of the plurality of electrodes after the delay time starting at after the power signal turn-off time to generate the electric field to substantially prevent the dust particle from falling comprises applying a positive voltage or a negative voltage between the two of the plurality of electrodes after the delay time sufficient to freeze the charge to generate an electric field to substantially suspend the dust particle. In some embodiments, applying the voltage signal between the two of the plurality of electrodes after the delay time starting at after the power signal turn-off time to generate the electric field to substantially prevent the dust particle from falling comprises applying a positive voltage having voltage steps or a negative voltage having voltage steps to the one of the plurality of electrodes after the delay time sufficient to freeze the charge to generate an electric field to substantially suspend the dust particle. In some embodiments, applying the voltage signal between the two of the plurality of electrodes after the delay time starting at after the power signal turn-off time to generate the electric field to substantially prevent the dust particle from falling comprises applying a positive voltage by turning the positive voltage on an off or a negative voltage by turning the negative voltage on and off to the one of the plurality of electrodes after the delay time sufficient to freeze the charge to generate an electric field to substantially suspend the dust particle. In some embodiments, the method further comprises including the plasma chamber in an extreme ultraviolet lithography system.

Consistent with disclosed embodiments, a method for controlling lifting of a dust particle in a plasma in a plasma chamber, the dust particle having a charge, is disclosed. The method comprises providing a particle lifting force in the plasma chamber during a late stage of a plasma afterglow after the charge is substantially frozen. In some embodiments, providing the particle lifting force in the plasma chamber during the late stage of the plasma afterglow after the charge is substantially frozen comprises generating a particle lifting force substantially equal to a force on the particle produced by gravity and a thermophoretic force. In some embodiments, generating the particle lifting force substantially equal to the force on the particle produced by gravity and the thermophoretic force comprises generating an electric field to produce the particle lifting force. In some embodiments, the method further comprises controlling the charge during an early stage of a plasma afterglow of the plasma before the charge is substantially frozen.

Consistent with disclosed embodiments, an apparatus is disclosed. The apparatus comprises a plasma chamber including a plurality of electrodes; and a system for controlling the plasma chamber, the system including a voltage source to provide a voltage signal to two of the plurality of electrodes and a delay circuit for delaying delivery of the voltage signal to the two of the plurality of electrodes after a power signal coupled through a capacitor to one of the plurality of electrodes is removed from the one of the plurality of electrodes. In some embodiments, the voltage signal is delivered directly from the voltage source to the two of the plurality of electrodes, without passing through the capacitor.

Consistent with disclosed embodiments, a system for controlling a charge on a particle in a plasma chamber and for controlling a lifting force applied to the particle is disclosed. The system comprises a plurality of electrodes included in the plasma chamber; a power control signal generator; a power source coupled to the power control signal generator and to two of the plurality of electrodes; a first delay circuit coupled to the power control signal generator, the first delay circuit to control delivery of a charge control voltage signal to two of the plurality of electrodes, the charge control voltage signal to control the charge on the particle in the plasma chamber; and a second delay circuit coupled to the power control signal generator, the second delay circuit to control delivery of a lifting control voltage signal to two of the plurality of electrodes, the lifting control voltage signal to control a force on the particle in the plasma chamber. In some embodiments, the system further comprises a tube fluidically coupled to the plasma chamber; and a tube control system for controlling a tube lifting force applied to the particle in the tube. In some embodiments, the system further comprises a load-lock fluidically coupled to the tube; and a load lock control system for controlling a load-lock lifting force applied to the particle in the load lock. In some embodiments, the system further comprises a gas source fluidically coupled to the plasma chamber; and a pump fluidically coupled to the plasma chamber.

### BRIEF DESCRIPTION OF THE DRAWINGS

FIG. 1 is a diagram illustrating one example of a system for use in semiconductor manufacturing to control particle contamination in a plasma afterglow.

FIG. 2 is another diagram of an example of a system for use in semiconductor manufacturing to control particle contamination in a plasma afterglow.

FIG. 3 is a logic diagram or timing diagram showing one example for applying DC potential at two times in order to control lifting force of particles in plasma afterglow.

FIG. 4 is a timing diagram showing an example of applying DC potential in a two-step process.

FIG. 5 illustrates another example of a timing diagram where amplitude of the RF waveform is adjusted to adjust the self-bias prior to extinguishing power.

FIG. 6 illustrates two separate potentials where the first potential is a spontaneous value due to a coupling capacitor.

FIG. 7 is a flow diagram illustrating one example of a method for use in semiconductor manufacturing to control particle contamination in a plasma afterglow.

FIG. 8 shows a flow diagram of a method for controlling charge on a dust particle during plasma afterglow in accordance with some embodiments of the present disclosure.

FIG. 9 shows a flow diagram of a method for controlling charge on a dust particle in accordance with some embodiments of the present disclosure.

FIG. 10 shows a flow diagram of a method for controlling charge on a dust particle during plasma afterglow in accordance with some embodiments of the present disclosure.

FIG. 11 shows a flow diagram of a method for controlling lifting of a dust particle in a plasma in a plasma chamber including a plurality of electrodes, the dust particle having a charge, in accordance with some embodiments of the present disclosure.

FIG. 12 shows a flow diagram of a method for controlling lifting of a dust particle in a plasma in a plasma chamber, the dust particle having a charge, in accordance with some embodiments of the present disclosure.

FIG. 13 shows a block diagram of an apparatus including a plasma chamber and a system for controlling the plasma chamber in accordance with some embodiments of the present disclosure.

FIG. 14 shows a flow diagram of a method for controlling a charge on a dust particle in accordance with some embodiments of the present disclosure.

FIG. 15 shows a block diagram of a wafer processing system including the plasma chamber as shown in FIG. 14 and further including a tube and a load-lock fluidically coupled to the plasma chamber and systems for lifting particles in the tube and load-lock in accordance with some embodiments of the present disclosure.

FIG. 16 illustrates a waveform of the potential on a powered electrode recorded by a monitor.

FIG. 17 illustrates the time variation of the height of a layer of particles as measured by a side-view camera, for three instances of the lifting electric field.

FIG. 18 shows a timing diagram for the method 1400 shown in FIG. 14 in accordance with some embodiments of the present disclosure. As shown in FIG. 18, the RF signal is modulated by turning it on and off. The DCI CONTROL turns on at t₁ and turns off at t₂ and the DC2 CONTROL tums on at t₃ and turns off at t₄. And as noted in the description of the experiment described above for the method shown in FIG. 14, the charge on the dust particle is negative.

### DETAILED DESCRIPTION

Methods, apparatus, and systems are shown and described for controlling the lifting force, F=QE, in a plasma afterglow, using a combination of two separate potentials during the afterglow. These potentials are applied to one or more electrodes at different times.

The first potential determines the residual charge Q; this potential may be either spontaneous (the potential remaining after the power source to a plasma chamber is turned off) or it may be controlled by an external power supply with a delay generator. If it is spontaneous, it may be a ‘self-bias’ potential due to the use of a capacitor to couple RF power or other signal to an electrode.

The second potential determines the electric field E. This potential is applied purposefully at a delayed time. The combination of a residual charge (which may be either spontaneous or controlled) and an electric field (which is controlled) will result in a controlled upward lifting force, in opposition to gravity. The user can adjust the power supply for the electric field (and optionally a power supply for the charging) to control this upward force. It is understood that the second potential can determine the electric field with or without a substance, including for example a substrate, that covers part or all of the electrode surface. If a dielectric substance covers part or all of the electrode surface, there can be an electric field resulting from a charge that is induced on the surface of that substance.

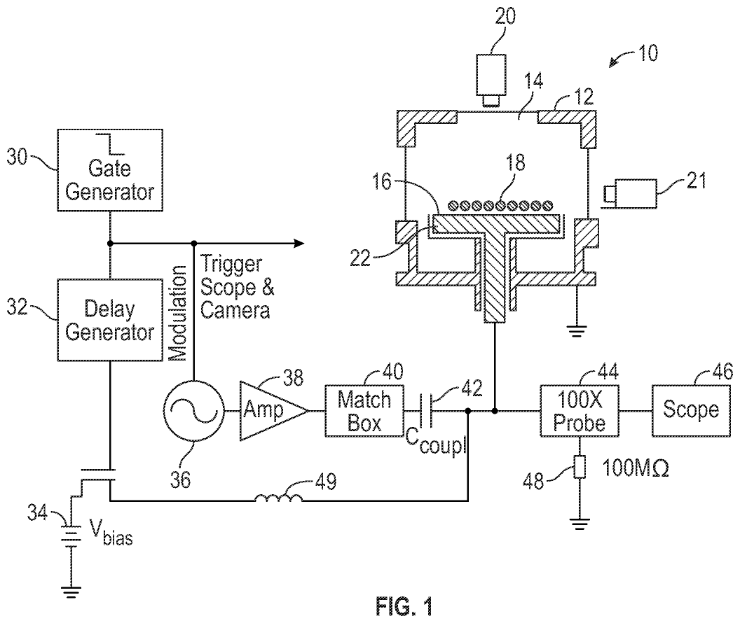

FIG. 1 is a diagram illustrating one example of a system 10 for use in semiconductor manufacturing to control particle contamination in a plasma afterglow. The system 10 includes a plasma chamber 12 which may be a plasma chamber in which a substrate is placed during plasma processing. A platform 22 is disposed within the plasma chamber 12 for supporting the substrate which may be positioned within the plasma chamber facing upward. The plasma chamber 12 is not limited to a particular size. In some embodiments, the plasma chamber 12 has a length of about 20.15 cm and a height above the platform 22 of about 9.9 cm. At least one electrode is located within the chamber, such as a bottom electrode 16 which may be present at the platform 22. A dust layer 18 is shown which includes small solid particles, typically less than about one micron in size which may fall onto a wafer during operation of the system 10. As used here, the term “particle” or “dust particle” or similar term is any substance in a plasma chamber that may accumulate charge and fall onto a surface, such as a wafer surface, and affect the yield in the manufacturing of integrated circuits fabricated on the substrate.

A top-view camera 20 and a side-view camera 21 are also shown. In some embodiments. the cameras 20, 21, laser beam 50 or other sensors may be used to monitor particles of the dust layer 18 such that the position of the particles is known and taken into consideration in determining lifting force. Where cameras or other optical sensors are used, the plasma chamber may have one or more windows to allow for viewing. In some embodiments, a laser beam imaging instrument may be used to provide planar measurements of the particles.

A gate generator 30 is shown which may be used to generate a voltage signal. A delay generator 32 is shown which introduces a delay before applying a signal to a transistor switch 34 for applying a voltage bias, Vbias, through a low-pass filter such as the inductor 49 to a common node with a coupling capacitor C_{coupl} and an oscilloscope probe 44 of an oscilloscope 46. A resistor 48 is shown electrically connecting the probe 44 to ground. The gate generator signal is applied to the modulation input of RF oscillator 36, and the output of that oscillator is applied to an amplifier 38 and matching network 40 as shown.

In some embodiments, in operation, to control the lifting force F=QE, a potential Vbias was applied in an experiment at a time of about 2 ms after switching off the RF plasma. In an experiment, this time was chosen because both electrons and ions had escaped the chamber, as judged by the voltage waveform on the lower electrode, so that only the particles (sometime referred to as dust particles) remained at that point, and their residual charge Q had already been established, i.e., its charge attained its “frozen” value. This timing was set using the delay generator 32. The additional circuit overcame the charge on the coupling capacitor within 100 us, so that the lower-electrode potential thereafter remained fixed at about +160.0 V, as compared to the ground potential of the other surfaces of the chamber. In this manner, the electric field E was forced to have an upward direction, at a controlled level, by t=about 2.1 ms.

The lifting electric force, in opposition to gravity, occurs after the transistor switch causes the lower electrode to change in potential. As a step toward controlling this lifting force, one can adjust the electric field at a specific time, as we have done. For one run of this experiment, we chose a potential of +170 V, which provided an electric field of 23.4 V/cm and had an effect of reducing the downward acceleration. For a second run of this experiment, we chose a potential of +200 V, which provided an electric field of 27.6 V/cm and had an effect of reversing the downward acceleration and lifting the particles. The timing for this adjustment of the potential was chosen based on our estimation of the time required for the charge to “freeze” in the plasma afterglow, i.e., the time required for the residual charge Q to be established.

Viewing from the side, we confirmed that the falling of the particles was slowed in one run and prevented in another run in this experiment by our reversal of the electric field. In the run with E=23.4 V/cm, the particles took at least three times longer than in a control run with zero electric field to impact on the lower electrode, starting from the same initial height=14.0 mm. In the run with E=27.6 V/cm, the particles did not fall to the lower electrode, but were lifted above their initial height.

It is to be understood that the system shown in FIG. 1 is merely one example of a system which may be used. For example, in this instance the circuit was used for experimental observation and thus the circuit could be simplified as needed in order to be integrated into a production environment. For example, in some embodiments, cameras, and oscilloscopes would not be needed, as timing and voltage controls could be pre-determined. In addition, although a particular configuration of a plasma chamber is shown, any number of different configurations may be used. For example, although a single electrode is shown near a bottom of the plasma chamber, one or more electrodes may be located elsewhere in the plasma chamber to help shape and control the electric field. It is further to be understood that the term “electrode” may include any conducting surface that faces the plasma, even if it mainly serves some other purpose.

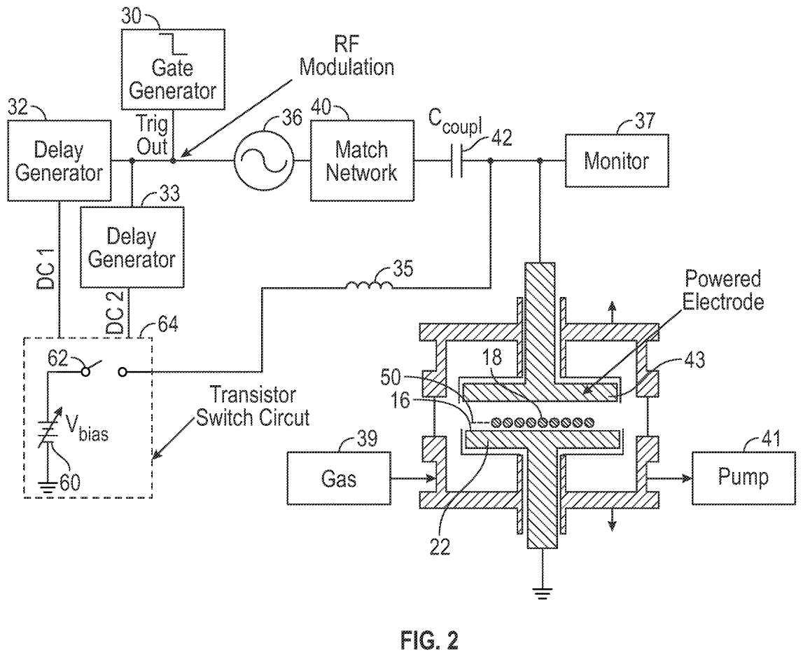

FIG. 2 is another diagram of an example of a system for use in semiconductor manufacturing to control particle contamination in a plasma afterglow. The system in FIG. 2 is similar to that shown in FIG. 1, there are two delay generators 32, 33 present which are operatively connected to a switching circuit 64 which provides for adjusting Vbias 60. Thus, a first voltage may be applied at a first time and a second voltage which may be different from the first voltage may be applied at a second time. Additionally, FIG. 2 differs from FIG. 1 by including another electrode which is powered instead of the lower electrode which is now grounded, and has a different monitor 37 of the voltage or current on the powered electrode, omits cameras and laser beams, and includes a pump 41 that can purge particles with gas flow provided by a gas source 39. Further, an inductor 35 couples an output of a switching circuit 64 to a powered electrode 43.

There may be more than two delay generators present, corresponding to more than two potentials which are applied in sequence. It should also be understood that the potential applied by the DC power supply may be programmed to different values for each application. For example, one magnitude and polarity for DC1 and a different magnitude and polarity for DC2, and so on for each potential which is applied.

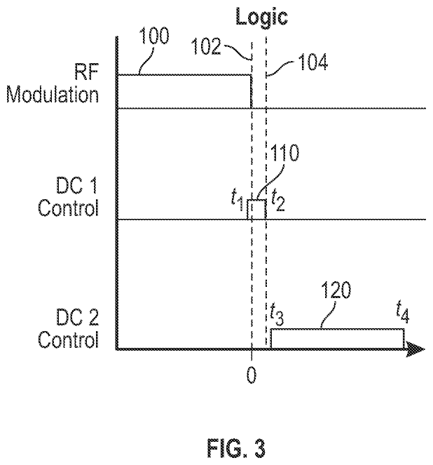

FIG. 3 is a logic diagram (also a timing diagram) showing one example for applying DC potential at two different times in order to control lifting force of particles in plasma afterglow. An RF modulation signal 100 is shown as is a first DC signal 110 and a second DC signal 120. The RF modulation signal 100 is switched off at a first time 102. The first DC signal 110 is shown switching on slightly before the RF modulation signal is switched off and remains on until a second time 104. The second DC signal 120 is switched on at the second time. Although a particular example of logic is shown in FIG. 3, it is to be understood that there may be variations in timing and voltages applied. For example, time at which the first DC signal begins need not be before the RF modulation signal ends 102 as shown. Instead, it may coincide with stopping the RF waveform, or it may be delayed (such as by tens or hundreds of microseconds) after stopping the RF modulation signal. It should also be understood there may be more than two potentials present which are applied in sequence and the potentials may have different magnitudes and/or polarities. It should also be understood that the RF modulation signal 100 may be applied to one or more electrodes.

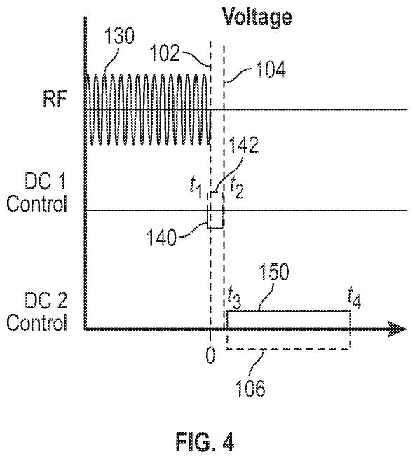

FIG. 4 is a timing diagram showing an example of applying DC potential in a two-step process. The example illustrated in FIG. 4 is related to the logic illustrated in FIG. 3 in that the times of interest in FIG. 3 correspond to the times of interest in FIG. 4. Note that polarity of applied potentials is shown here. An RF signal 130 is shown which is used to sustain the ionization of the plasma, the RF signal switching off at time 0 (shown by line 102). Slightly before the RF signal is switched off, t₁ occurs which is when the first DC voltage 140 is switched on for a first duration extending from t₁ to t₂. Subsequently, the second DC voltage 150 is switched on from t₃ to t₄. In this example, the polarity of the first DC voltage 140 is negative while the polarity of the second DC voltage 150 is positive. Thus, it is to be understood that these voltages are different. The present invention provides for different voltages as may be desirable for controlling the residual charge as well as the electric field. In addition, as shown, the second duration from t₃ to t₄ is significantly longer than the first duration from t₁ to t₂. The potentials for the charging-control step(s) and the lifting-control step(s) can be applied to electrode(s) that are the lower electrode, and/or an electrode(s) or conducting surfaces located above a lower electrode or elsewhere in the chamber.

Alternative polarity for the DC potential(s) for charging control 142, and/or the lifting-force control 106, may be used. Example situations where these alternative polarities may be chosen include (a) when the controlled electrode is located in an upper or side position rather than a lower position, (b) when negative ions are abundant as can occur in etching or deposition processes, (c) when it is desired for charge control for the particles to collect negative charges (electrons or negative ions) versus positive charges (positive ions) from the plasma, and (d) when the natural time scales in the plasma afterglow are different from the canonical sequence of first most electrons undergoing transport out of the chamber's volume, and then a freezing of the charge followed by most ions undergoing transport out of the chamber's volume.

Thus, as shown in FIG. 4, as a first step a DC potential may be applied, or that potential may appear spontaneously (i.e., self-bias potential) with the effect of controlling the residual charge Q, and later in a second step a DC potential may be applied to control the electric field E. The product of Q and E is the lifting force. Thus, the lifting force is controlled by a combination of controlling the charging and electric field through at least two steps of electric potentials applied to electrode(s).

Although a particular example is shown in FIG. 4. it is to be understood that there may be variations in timing and voltages applied. It is to be further understood that RF waveforms at one or more frequencies may be applied. In addition, the RF waveforms may be applied to one or more electrodes, may be switched off at one or more times, or may be coupled to the plasma chamber through one or more applications of inductive or capacitive coupling.

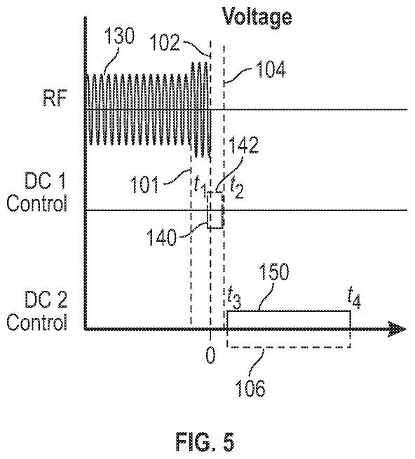

FIG. 5 illustrates another example of a timing diagram. Note that in FIG. 5, the amplitude of the RF waveform is greater at time 101 than previously. Thus, there may be a change in the RF amplitude shortly before extinguishing the RF power as one approach to controlling charging. This change in the RF amplitude before t =0 provides for adjusting the self-bias before extinguishing the RF power.

Thus, it is to be understood that control of the residual charge may be generated in multiple different ways such as by adjustment of the RF amplitude before time t=0, or the purposeful application of a control potential DCI mostly or entirely after t=0, or both.

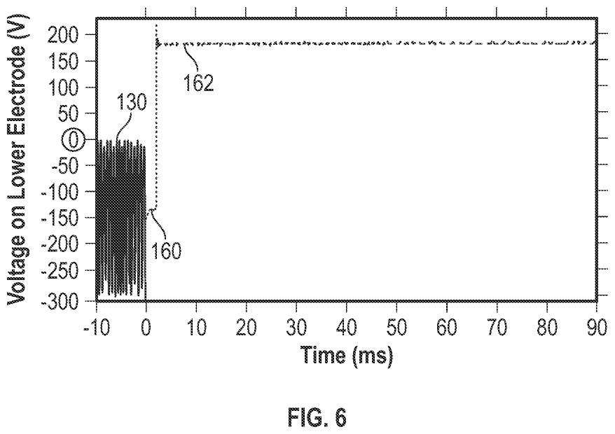

FIG. 6 illustrates a sequence of two steps where the first potential is a spontaneous value due to a coupling capacitor. In this example, an RF signal 130 is shown with its ending time at t=0, and then a first potential 160 which is a spontaneous value persists. Later a potential 162 is applied. This later potential controls the electric field during the time that the particles would be falling, after all the electrons and ions are mostly gone. In this example, later potential was applied at a time of 2.1 ms.

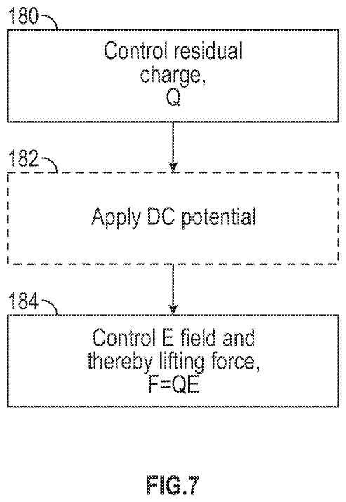

FIG. 7 is a flow diagram illustrating one example of a method for use in semiconductor manufacturing to control particle contamination in a plasma afterglow. In step 180, a residual charge is controlled. As previously explained. this charge may be controlled in a number of different ways. This may include changing the RF amplitude in order to adjust the self-bias before extinguishing the RF power. The residual charge may also be controlled by application of DC potential(s) to one or more electrodes in one or more increments or periods. This may occur at t=0 when RF power is extinguished but may occur earlier or later. The residual charge may also be controlled by both changing the RF amplitude and application of DC potential(s) to one or more electrodes. Alternatively, as previously explained, one may rely solely on the spontaneous self-bias potential(s) on the one or more electrodes to determine the residual charge.

Next, an optional step 182 is shown. In some embodiments, for the purpose of both finishing the control of the residual charge Q and starting the control of the E field and thereby the lifting force, F=QE, the method may include application of one or more DC potentials to one or more electrodes in one or more increments or periods. Such a step may be considered a transition step. This may be desirable in that there may be some overlap in times that the charge has not quite frozen yet, but it is desirable to begin applying a lifting force.

Next, in step 184, the electric field is controlled and thereby the lifting force, F=QE is controlled. The E field may be controlled by application of one or more DC potentials to one or more electrodes in one or more increments or periods. This may occur so as to overlap with period(s) when non-downward forces are applied to push/pull particles away from the substrate such as by applying drag force from purge gas, thermophoretic force, electric force, or other forces.

Although examples of potentials, and timings for applying potentials have been provided, it is to be understood that these are merely examples and that the methods and systems shown and described herein may be adapted or optimized to particular production environments. This may take into account, for example, the number of instances that the potential is changed on an electrode, the size of a plasma chamber, how quickly particles are removed from the chamber such as through the use of drag forces from purge gas or thermophoretic forces from gas temperature gradients, to push the particles to a desired location, the amount of delay required for the particle charge to freeze, the amount of delay required to avoid particles contacting a substrate of a surface, the application of horizontal electric fields to push or pull particles away from a substrate, or other appropriate factors.

Although various examples have been shown, the present invention contemplates numerous variations, options, and alternatives. For example, instead of using RF power to create a plasma, other types of power may be used such as microwave power. Although a particular example of a plasma chamber is shown, other types of plasma chambers may be present as may be appropriate for a particular production environment.

It is to be further understood, that the initial charging that results in the residual charge can be obtained in any number of ways. This includes purposefully applying DC potential(s) to one or more electrodes. This further includes allowing a naturally occurring potential to develop on an electrode (this is the so-called “self-bias” potential, which persists after extinguishing the plasma) due to the coupling capacitor. This may further include a sequence of first relying on the self-bias potential and then later purposefully applying a potential.

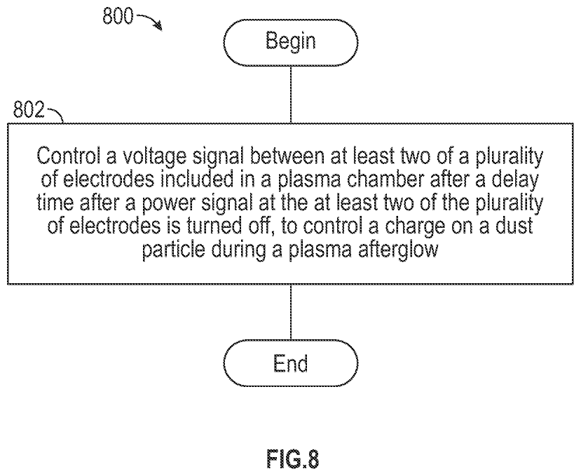

FIG. 8 shows a flow diagram of a method 800 for controlling a charge on a dust particle during plasma afterglow in accordance with some embodiments of the present disclosure. The method 800 includes controlling a voltage signal between at least two of a plurality of electrodes included in a plasma chamber after a delay time after a power signal at the at least two of the plurality of electrodes is turned off, to control the charge (block 802). In some embodiments, controlling the voltage signal comprises for the voltage signal having a polarity and magnitude, controlling the polarity of the voltage signal and controlling the magnitude of the voltage signal. In some embodiments, the power signal is a radio frequency power signal. In some embodiments, the delay time is less than about one hundred milliseconds. In some embodiments, the charge is between about −10e and about +10e per nanometer of diameter or length of the dust particle. In some embodiments, the plasma chamber is included in an extreme ultraviolet lithography system.

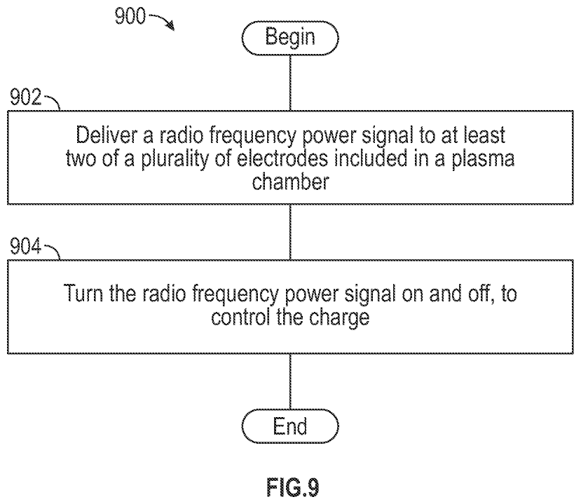

FIG. 9 shows a flow diagram of a method 900 for controlling a charge on a dust particle in accordance with some embodiments of the present disclosure. The method 900 includes delivering a radio frequency power signal to at least two of a plurality of electrodes included in a plasma chamber (block 902); and turning the radio frequency power signal on and off, to control the charge (block 904). In some embodiments, the method 900 further includes varying the rate at which the radio frequency power signal is turned on and off. In some embodiments, turning the radio frequency power signal on and off, to control the charge includes turning the radio frequency power on and off to cause the charge to have a negative value.

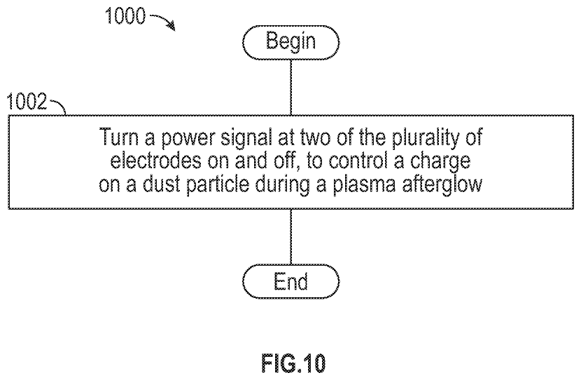

FIG. 10 shows a flow diagram of a method 1000 for controlling a charge on a dust particle during a plasma afterglow in accordance with some embodiments of the present disclosure. The method 1000 includes turning a power signal at two of the plurality of electrodes on and off to control the charge (block 1002). In some embodiments, turning the power signal at two of the plurality of electrodes on and off to control the charge includes turning a radio frequency signal at two of the plurality of electrodes on and off to control the charge.

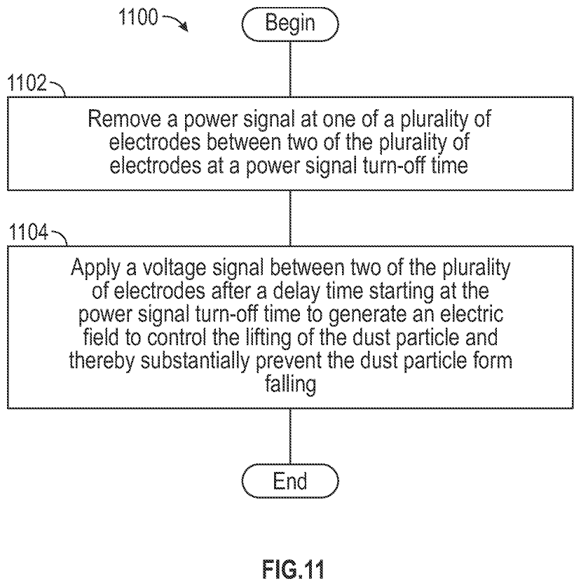

FIG. 11 shows a flow diagram of a method 1100 for controlling lifting of a dust particle in a plasma in a plasma chamber including a plurality of electrodes, the dust particle having a charge, in accordance with some embodiments of the present disclosure. The method 1100 includes removing a power signal at one of a plurality of electrodes between two of the plurality of electrodes at a power signal turn-off time (block 1102); and applying a voltage signal between the two of the plurality of electrodes after a delay time starting at the power signal tum-off time to generate an electric field to control the lifting of the dust particle and thereby substantially prevent the dust particle from falling (block 1104).

In some embodiments, applying the voltage signal between the two of the plurality of electrodes after the delay time starting at the power signal tum-off time to generate the electric field to substantially prevent the dust particle from falling includes applying a positive voltage or a negative voltage between the two of the plurality of electrodes after the delay time sufficient to substantially freeze the charge.

In some embodiments, applying the voltage signal between the two of the plurality of electrodes after the delay time starting at after the power signal turn-off time to generate the electric field to substantially prevent the dust particle from falling includes applying a positive voltage or a negative voltage between the two of the plurality of electrodes after the delay time sufficient to freeze the charge to generate an electric field to substantially suspend the dust particle.

In some embodiments, applying the voltage signal between the two of the plurality of electrodes after the delay time starting at after the power signal turn-off time to generate the electric field to substantially prevent the dust particle from falling includes applying a positive voltage having voltage steps or a negative voltage having voltage steps to the one of the plurality of electrodes after the delay time sufficient to freeze the charge to generate an electric field to substantially suspend the dust particle.

In some embodiments, applying the voltage signal between the two of the plurality of electrodes after the delay time starting at after the power signal turn-off time to generate the electric field to substantially prevent the dust particle from falling includes applying a positive voltage by turning the positive voltage on an off or a negative voltage by turning the negative voltage on and off to the one of the plurality of electrodes after the delay time sufficient to freeze the charge to generate an electric field to substantially suspend the dust particle.

In some embodiments, the method 1100 further includes including the plasma chamber in an extreme ultraviolet lithography system.

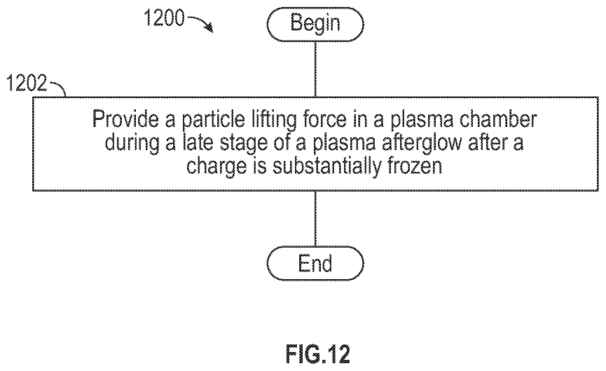

FIG. 12 shows a flow diagram of a method 1200 for controlling lifting of a dust particle in a plasma in a plasma chamber, the dust particle having a charge, in accordance with some embodiments of the present disclosure. The method 1200 includes providing a particle lifting force in the plasma chamber during a late stage of a plasma afterglow after the charge is substantially frozen (block 1202). In some embodiments, providing the particle lifting force in the plasma chamber during the late stage of the plasma afterglow after the charge is substantially frozen includes generating a particle lifting force substantially equal to a force on the particle produced by gravity and a thermophoretic force. In some embodiments, generating the particle lifting force substantially equal to the force on the particle produced by gravity and the thermophoretic force includes generating an electric field to produce the particle lifting force. In some embodiments, the method 1200 further includes controlling the charge during an early stage of a plasma afterglow of the plasma before the charge is substantially frozen.

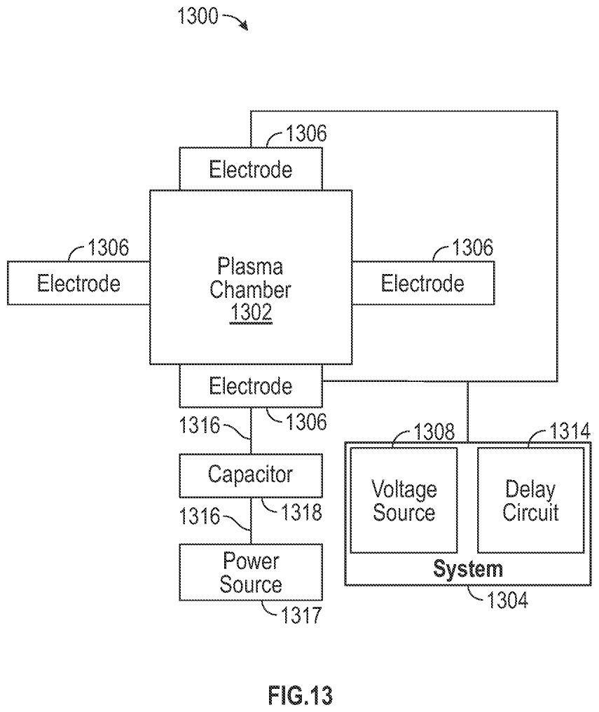

FIG. 13 shows a block diagram of an apparatus 1300 including a plasma chamber 1302 and a system 1304 for controlling the plasma chamber 1302 in accordance with some embodiments of the present disclosure. The plasma chamber 1302 includes a plurality of electrodes 1306. The system 1304 for controlling the plasma chamber 1302 includes a voltage source 1308 to provide a voltage signal 1310 to two of the plurality of electrodes 1306 and a delay circuit 1314 for delaying delivery of the voltage signal 1310 to the two of the plurality of electrodes 1306 after a power signal 1316, provided by a power source 1317, coupled through a capacitor 1318 to one of the plurality of electrodes 1306 is removed from the one of the plurality of electrodes 1306. In some embodiments, the voltage signal 1310 is delivered directly from the voltage source 1308 to the two of the plurality of electrodes 1306, without passing through the capacitor 1318.

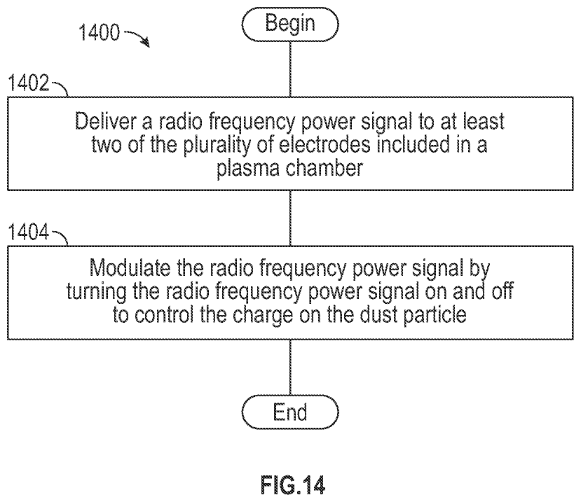

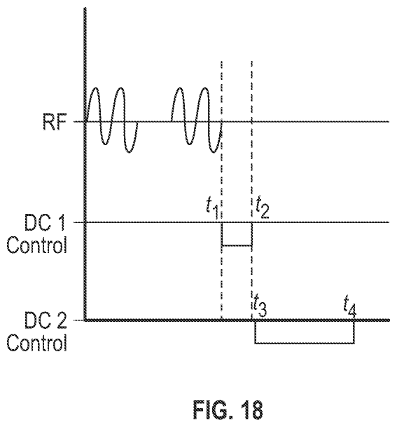

FIG. 14 shows a flow diagram of a method 1400 for controlling a charge on a dust particle in accordance with some embodiments of the present disclosure. (See FIG. 18 for the corresponding timing diagram.) The method 1400 includes delivering a radio frequency power signal to at least two of a plurality of electrodes included in a plasma chamber (block 1402); and modulating the radio frequency power signal by turning the radio frequency power signal on and off to control the charge on the dust particle (1404). In some embodiments, modulating the radio frequency power signal by turning the radio frequency power signal on and off to control the charge on the dust particle includes modulating the radio frequency power signal by turning the radio frequency power signal on and off to cause the charge to have a positive value. In some embodiments, the method 1400 further includes controlling a voltage signal between at least two of a plurality of electrodes included in a plasma chamber after a delay time after the radio frequency power signal at the at least two of the plurality of electrodes is turned off, to control the charge.

The following laboratory test was performed with the result that a charge on a particle in the afterglow was found to be negative. In that test, before turning-off the RF power, the duty cycle of the RF power was reduced to 3.5% (35 microsec on 965 microsec off) with a low amplitude of 296 Volts peak-to-peak. In that demonstration experiment, performed with an argon plasma, the lower electrode retained a DC potential of −25 volts after the plasma power was turned off and no DC voltage was applied to that lower electrode during the afterglow (i.e., this method of charge control was done instead of using DC power supplies). In the demonstration experiment, the 8.69-micron particles retained a negative charge measured to be 20,000e. One explanation of when the charge on the dust particle was controlled to have a negative value, instead of a positive value, is that the low duty cycle of the RF power caused the time-average ion density to be so low in the plasma, at the time that the RF power was turned off, that the dust could not collect any significant positive charge from collecting these small numbers of ions in the early afterglow; in other words, the charge of the dust particle became substantially frozen just as soon as the RF power was turned off.

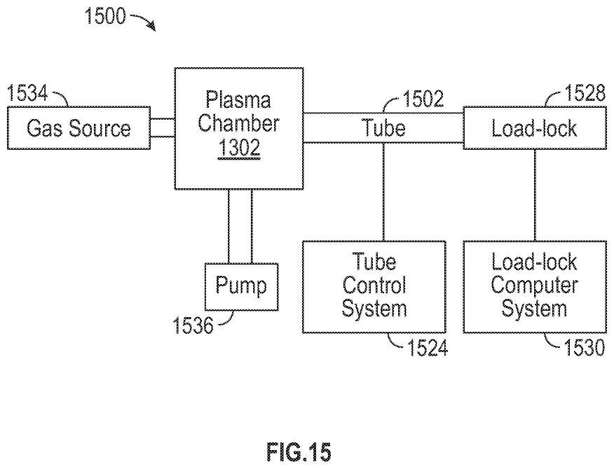

FIG. 15 shows a block diagram of a wafer processing system 1500 including the plasma chamber 1302 as shown in FIG. 14 and further including a tube 1502 and a load-lock 1528 fluidically coupled to the plasma chamber 1302 and systems for lifting particles in the tube 1502 and load-lock 1528 in accordance with some embodiments of the present disclosure. The tube control system 1524 provides a lifting force to prevent particles passing through the tube 1502 from falling onto a surface of the tube 1502. The lifting force is generated by an electric field implemented in the tube 1502. The load-lock control system 1530 provides a lifting force to prevent particles passing through the load-lock 1528 from settling onto a surface of the load-lock 1528. The lifting force is generated by an electric field implemented in the load-lock 1528. To move particles through the wafer processing system 1500 the system 1500 includes a gas source 1534 and a pump 1536 which are fluidically coupled to the plasma chamber 1302 and other components (not shown) of the wafer processing system 1500.

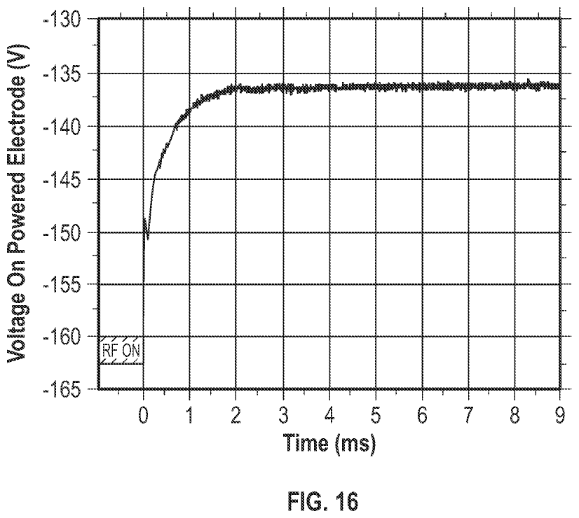

FIG. 16 illustrates a waveform of the potential on a powered electrode recorded by a monitor. In this example, during the first step of charging the particles, the powered electrode had a negative potential to attract positive ions, and this collection of positive ions gradually altered the potential on powered electrode by altering the charge stored in the coupling capacitor until the potential and charge attained nearly steady values. An inspection of this waveform can be included as part of the method, so that the timing for the end of the charging control and beginning of the lifting control can be chosen, for example after the change in the potential exceeds a desired fraction of the total change.

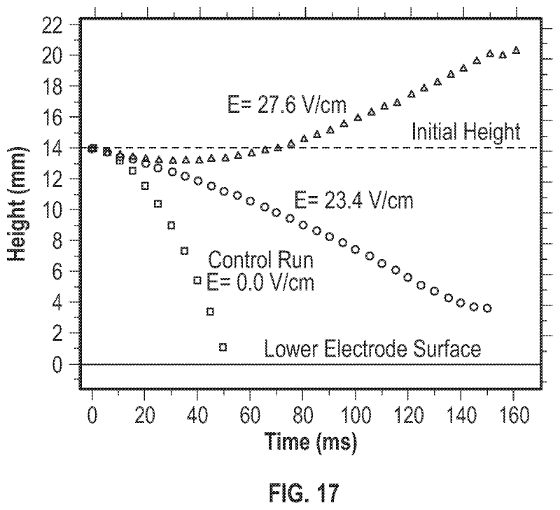

FIG. 17 illustrates the time variation of the height of a layer of particles as measured by a side-view camera, for three instances of the lifting electric field. In one operation, to control the lifting force, runs were performed with three values of the lifting electric field. In a control run with zero value of the electric field, the particle layer fell from its initial height of about 14 mm to the lower electrode surface in approximately 50 ms. In a run with E=23.4 V/cm beginning after a delay of 2 ms, the falling of the particles to the lower electrode was slowed approximately three-fold, and in a run with E=27.6 V/cm the particles were prevented from falling and were lifted above their initial height.

FIG. 18 shows a timing diagram for the method 1400 shown in FIG. 14 in accordance with some embodiments of the present disclosure. As shown in FIG. 18, the RF signal is modulated by turning it on and off. The DC1 CONTROL tums on at t₁ and turns off at t₂ and the DC2 CONTROL tums on at t₃ and turns off at t₄. This example shows a method of controlling the residual charge in the afterglow so that that charge is negative instead of positive as is often the outcome when the plasma power is operated without the modulation described in FIG. 18.

The following laboratory test was performed with the result that a charge on a particle in the afterglow was found to be negative. In that test, before turning-off the RF power, the duty cycle of the RF power was reduced to 3.5% (35 microsec on 965 microsec off) with a low amplitude of 296 Volts peak-to-peak. In that demonstration experiment, performed with an argon plasma, the lower electrode retained a DC potential of −25 volts after the plasma power was turned off and no DC voltage was applied to that lower electrode during the afterglow (i.e., this method of charge control was done instead of using DC power supplies). In the demonstration experiment, the 8.69-micron particles retained a negative charge measured to be 20,000e. One explanation of when the charge on the dust particle was controlled to have a negative value, instead of a positive value, is that the low duty cycle of the RF power caused the time-average ion density to be so low in the plasma, at the time that the RF power was turned off, that the dust could not collect any significant positive charge from collecting these small numbers of ions in the early afterglow; in other words, the charge of the dust particle became substantially frozen just as soon as the RF power was turned off.

Reference throughout this specification to “an embodiment,” “some embodiments,” or “one embodiment.” means that a particular feature, structure, material, or characteristic described in connection with the embodiment is included in at least one embodiment of the present disclosure. Thus, the appearances of the phrases such as “in some embodiments,” “in one embodiment,” or “in an embodiment,” in various places throughout this specification are not necessarily referring to the same embodiment of the present disclosure. Furthermore, the particular features, structures, materials, or characteristics may be combined in any suitable manner in one or more embodiments.

All publications (including Neeraj Chaubey and J. Goree, Controlling the charge of dust particles in a plasma afterglow by timed switching of an electrode voltage, Journal of Physics D, Vol. 56, art. no. 375202 June 2023), patents, and patent documents are incorporated by reference herein, as though individually incorporated by reference. The invention has been described with reference to various specific and preferred embodiments and techniques. However, it should be understood that many variations and modifications may be made while remaining within the spirit and scope of the invention.

1. A method for controlling a charge on a dust particle during a plasma afterglow, the method comprising:
controlling a voltage signal between at least two of a plurality of electrodes included in a plasma chamber after a delay time after a power signal at the at least two of the plurality of electrodes is turned off, to control the charge.

2. The method of claim 1, wherein controlling the voltage signal comprises:
for the voltage signal having a polarity and magnitude, controlling the polarity of the voltage signal and controlling the magnitude of the voltage signal.

3. The method of claim 2, wherein the power signal is a radio frequency power signal.

4. The method of claim 1, wherein the delay time is less than about one hundred milliseconds.

5. The method of claim 1, wherein the charge is between about −10e and about +10e per nanometer of diameter or length of the dust particle.

6. The method of claim 1, wherein the plasma chamber is included in an extreme ultraviolet lithography system.

7-23. (canceled)

24. A system for controlling a charge on a particle in a plasma chamber and for controlling a lifting force applied to the particle, the system comprising:
a plurality of electrodes included in the plasma chamber;
a power control signal generator;
a power source coupled to the power control signal generator and to two of the plurality of electrodes;
a first delay circuit coupled to the power control signal generator, the first delay circuit to control delivery of a charge control voltage signal to two of the plurality of electrodes, the charge control voltage signal to control the charge on the particle in the plasma chamber; and
a second delay circuit coupled to the power control signal generator, the second delay circuit to control delivery of a lifting control voltage signal to two of the plurality of electrodes, the lifting control voltage signal to control a force on the particle in the plasma chamber.

25. The system of claim 24, further comprising:
a tube fluidically coupled to the plasma chamber; and
a tube control system for controlling a tube lifting force applied to the particle in the tube.

26. The system of claim 25, further comprising:
a load-lock fluidically coupled to the tube; and
a load lock control system for controlling a load-lock lifting force applied to the particle in the load lock.

27. The system of claim 26, further comprising
a gas source fluidically coupled to the plasma chamber; and
a pump fluidically coupled to the plasma chamber.

28. A method for controlling a charge on a dust particle, the method comprising:
delivering a radio frequency power signal to at least two of a plurality of electrodes included in a plasma chamber; and
modulating the radio frequency power signal by turning the radio frequency power signal on and off to control the charge on the dust particle.

29. The method of claim 28, wherein modulating the radio frequency power signal by turning the radio frequency power signal on and off to control the charge on the dust particle comprises:
modulating the radio frequency power signal by turning the radio frequency power signal on and off to cause the charge to have a positive value.

30. The method of claim 29, further comprising:
controlling a voltage signal between at least two of a plurality of electrodes included in a plasma chamber after a delay time after the radio frequency power signal at the at least two of the plurality of electrodes is turned off, to control the charge.
